(19) United States
(12) Patent Application Publication
(10) Pub. No.: US 2008/0296475 A1
(43) Pub. Date: Dec. 4, 2008

(54) Vertical image sensors and methods of fabricating the same

(75) Inventor: Taek Kim, Seongnam-si (KR)

Correspondence Address: HARNESS, DICKEY & PIERCE, P.L.C., P.O. BOX 8910, RESTON, VA, 20195, US

(73) Assignee: SAMSUNG ELECTRONICS CO., LTD

(21) Appl. No.: 12/005,369

(22) Filed: Dec. 27, 2007

(30) Foreign Application Priority Data
May 31, 2007 (KR) 10-2007-0053473

(51) Int. Cl. H01L 27/00; H01L 31/00

(52) U.S. Cl. 250/208.1; 257/461; 257/E31.001

(57) ABSTRACT

A vertical CMOS image sensor includes a plurality of photodiodes formed vertically in a substrate to a first depth. The vertical CMOS image sensor further includes a plurality of signal processing devices formed to correspond to the plurality of photodiodes. The plurality of signal processing devices are formed to transmit signals generated from the plurality of photodiodes. Each of the signal processing devices is substantially formed on the same plane with a corresponding one of the plurality of photodiodes.

### PRIORITY STATEMENT

This application claims priority under 35 U.S.C. §119 to Korean Patent Application No. 10-2007-0053473, filed on May 31, 2007, in the Korean Intellectual Property Office, the entire contents of which is incorporated herein by reference.

### BACKGROUND

### Description of the Related Art

A conventional image sensor is a photoelectric element that transforms detected light into an electric signal. A conventional image sensor may include a plurality of unit pixels arranged in an array on a semiconductor substrate. Each of the unit pixels may include a photodiode and a plurality of transistors. The photodiode may generate and store optical charges in response to detected, external light. The transistors may output electrical signals according to the generated optical charges.

A conventional complimentary metal-oxide semiconductor (CMOS) image sensor may include a photodiode that stores received optical signals. Such a CMOS image sensor may generate an image using a control device that controls and/or processes optical signals. If the control device is manufactured using conventional CMOS manufacturing techniques, the process of manufacturing a conventional CMOS image sensor may be simplified, for example, by being formed in a single chip.

A conventional CMOS image sensor may further include a color filter that selects light of a particular wavelength. Because conventional color filters absorb approximately 2/3 of the light incident on the photodiode, the amount of light transmitted to the photodiode may decrease, thereby reducing the sensitivity of the CMOS image sensor.

Alternatively, conventional CMOS image sensors may omit a color filter. However, such conventional CMOS image sensors may have a more complicated signal processing wire structure in which electrical signals are output from vertically formed photodiodes. As a result, the process of manufacturing the conventional CMOS sensor may be more complex.

### SUMMARY

Example embodiments relate to image sensors, for example, vertical CMOS image sensors and methods of fabricating the same.

Example embodiments provide CMOS image sensors having a simpler structure for connecting signal process control devices to vertically formed photodiodes, and methods of fabricating the same.

According to at least one example embodiment, a vertical CMOS image sensor may include a plurality of photodiodes and a plurality of signal processing devices. Each of the plurality of photodiodes may be formed vertically to a desired depth in a substrate. The plurality of signal processing devices may be formed to correspond to the plurality of photodiodes, and may transmit signals generated from the plurality of photodiodes. Each signal processing device may be formed on the same or substantially the same plane as a corresponding photodiode.

According to example embodiments, the signal processing device may include a floating diffusion region that receives charges from the corresponding photodiode. A doping region (e.g., an n-type doping region) of the photodiode and the floating diffusion region form a transfer transistor together with a transfer gate arranged above a region between the doping region of the photodiode and the floating diffusion region.

According to at least some example embodiments, the plurality of photodiodes may include three photodiodes. The three photodiodes may be regions that detect blue, green and red light, respectively. The photodiode may include the doping region and a region (e.g., p-type region) around the doping region. The floating diffusion region may be an n+ type doping region. The doping regions of the photodiodes may be formed vertically in the same or substantially the same region of the substrate.

According to at least some example embodiments, the plurality of photodiodes may be aligned vertically with one another such that light incident on the vertical CMOS image sensor impinges an uppermost one of the plurality of photo diodes prior to impinging a lower of the plurality of photodiodes.

According to at least some example embodiments, the plurality of photodiodes may include at least a first, second and third photodiode, and the plurality of signal processing devices may include at least a first, second and third signal processing device. A bottom portion of the first photodiode may be formed in a same first plane as a bottom portion of the first signal processing device, a top portion of the second photodiode may be formed in a same second plane as a top portion of the second signal processing device, and a top portion of the third photodiode may be formed in a same third plane as a top portion of the third signal processing device. The same second plane may be at a first depth below a surface of the substrate and the same third plane may be at a second depth below a surface of the substrate. The second depth being greater than the first depth.

At least one other example embodiment provides a method of fabricating a vertical CMOS image sensor. In at least this example embodiment, an epitaxy layer may be formed. The epitaxy layer may include first (e.g., p-type) doping layers and second (e.g., n-type) doping layers formed alternately on a substrate. A plurality of vertical photodiode regions may be defined, and a plurality of signal processing device regions may be formed by implanting a first (e.g., p-type) impurity from an upper side of the epitaxy layer. Each of the plurality of signal processing regions may be connected to a corresponding photodiode region. A signal processing device region connected to a first photodiode may be doped (e.g., with n+ impurities). The first photodiode may include a first photodiode region from a first surface of the epitaxy layer.

A second surface exposing a portion of a second doping layer may be formed by etching a signal processing region connected to a second photodiode. The second photodiode may include a second photodiode region from the first surface of the epitaxy layer. The signal processing device region in the second surface may be doped with, for example, n+ impurities. The epitaxy layer may be a silicon layer or the like.

According to at least some example embodiments, a third surface exposing a portion of a third n type doping layer may be formed by etching a signal processing region connected to a third photodiode. The third photodiode may include a third photodiode region from the first surface of the epitaxy layer. The signal processing device region in the third surface may be doped with, for example, n+ impurities.

According to at least some example embodiments, the defining of the plurality of signal processing device regions may include defining the a first signal processing device formed on the first surface, defining the a second signal processing device region formed on the second surface, and defining the a third signal processing device region formed on the third surface. The second surface may be at a first depth below the first surface, and the third surface may be at a second depth below the first surface. The second depth may be greater than the first depth.

### BRIEF DESCRIPTION OF THE DRAWINGS

Example embodiments will become more apparent by describing in detail the example embodiments shown in the attached drawings in which:

FIG. 1 is a plan view of a vertical CMOS image sensor according to an example embodiment;

FIGS. 2 and 3 are cross-sectional views taken along line II-II and III-III of FIG. 1, respectively;

FIG. 4 is an equivalent circuit of a unit pixel according to an example embodiment;

FIGS. 5A through 5D are cross-sectional views illustrating a method of fabricating an image sensor according to another example embodiment.

### DETAILED DESCRIPTION OF EXAMPLE EMBODIMENTS

Various example embodiments will now be described more fully with reference to the accompanying drawings in which some example embodiments are shown. In the drawings, the thicknesses of layers and regions are exaggerated for clarity.

Detailed illustrative example embodiments are disclosed herein. However, specific structural and functional details disclosed herein are merely representative for purposes of describing example embodiments. This invention may, however, may be embodied in many alternate forms and should not be construed as limited to only the example embodiments set forth herein.

Accordingly, while example embodiments are capable of various modifications and alternative forms, embodiments thereof are shown by way of example in the drawings and will herein be described in detail. It should be understood, however, that there is no intent to limit example embodiments to the particular forms disclosed, but on the contrary, example embodiments are to cover all modifications, equivalents, and alternatives falling within the scope of the invention. Like numbers refer to like elements throughout the description of the figures.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of example embodiments. As used herein, the term “and/or,” includes any and all combinations of one or more of the associated listed items.

It will be understood that when an element or layer is referred to as being “formed on,” another element or layer, it can be directly or indirectly formed on the other element or layer. That is, for example, intervening elements or layers may be present. In contrast, when an element or layer is referred to as being “directly formed on,” to another element, there are no intervening elements or layers present. Other words used to describe the relationship between elements or layers should be interpreted in a like fashion (e.g., “between,” versus “directly between,” “adjacent,” versus “directly adjacent,” etc.).

The terminology used herein is for the purpose of describing particular embodiments only and is not intended to be limiting of example embodiments. As used herein, the singular forms “a,” “an,” and “the,” are intended to include the plural forms as well, unless the context clearly indicates otherwise. It will be further understood that the terms “comprises,” “comprising,” “includes,” and/or “including,” when used herein, specify the presence of stated features, integers, steps, operations, elements, and/or components, but do not preclude the presence or addition of one or more other features, integers, steps, operations, elements, components, and/or groups thereof.

Vertical CMOS image sensors and methods of fabricating the same according to example embodiments will now be described more fully with reference to the accompanying drawings.

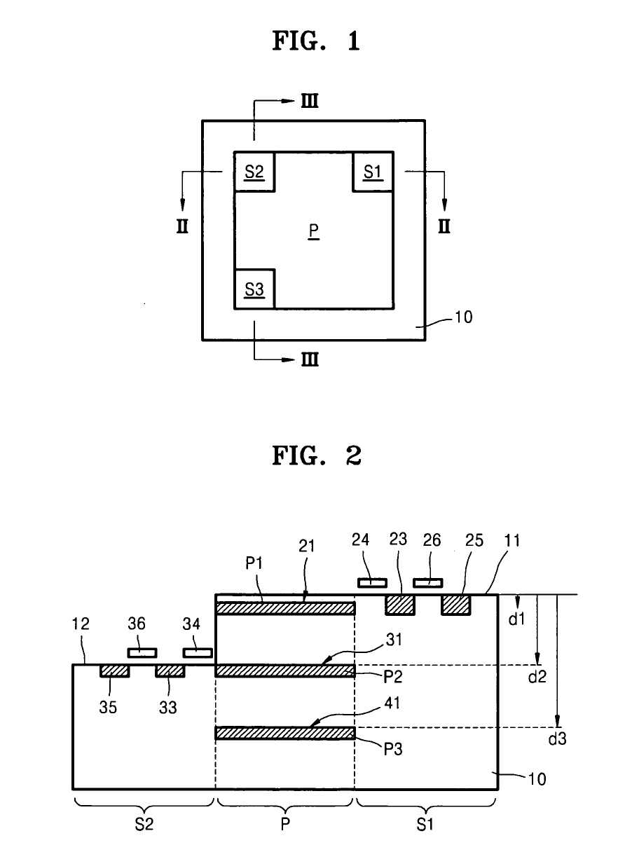

FIG. 1 is a plan view of a vertical CMOS image sensor according to an example embodiment. As shown, the vertical CMOS image sensor may be formed in/on a substrate 10. For the sake of clarity, micro-lenses and wirings between micro lenses and the substrate 10 are omitted from the drawings.

Referring to FIG. 1, a photodiode region P and signal processing regions S1 through S3 may be formed on the silicon substrate 10. The signal processing regions S1 through S3 may be connected and/or adjacent to the photodiode region P. The first region S1 may be formed on a surface of the silicon substrate 10. The second region S2 may be formed in the silicon substrate 10 to a first depth from the surface of the silicon substrate 10. The third region S3 may be formed in the silicon substrate 10 to a second depth from the surface of the silicon substrate 10.

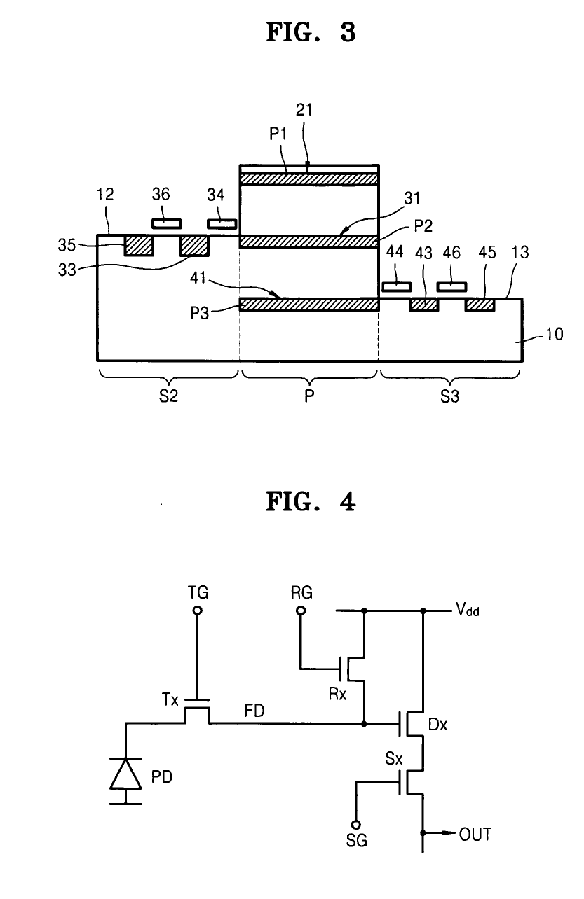

FIGS. 2 and 3 are cross-sectional views taken along lines II-II and III-III of FIG. 1, respectively.

Referring to FIGS. 1 and 2, the substrate 10 may be a silicon substrate doped with a first impurity (e.g., a p-type impurity). The photodiode region P may include a plurality of (e.g., three) regions P1 through P3. The plurality of regions P1 to P3 may be formed at first through third depths d1 through d3, respectively, from a first surface 11 of the silicon substrate 10. The plurality of regions P1 to P3 may be doped with a second impurity (e.g., n-type impurity). The first impurity may be different from the second impurity. In this example, the depths d1, d2 and d3 may be approximately 0.2 μm, 0.6 μm, and 2 μm, respectively. The plurality of doping regions P1 through P3 may absorb wavelengths of blue light, green light, and red light, respectively.

The doping regions P1 through P3 together with surrounding (e.g., p-type) regions around each of the doping regions P1 through P3 may form first through third photodiodes 21, 31, and 41, respectively. The first photodiode 21 may be a blue photodiode, the second photodiode 31 may be a green photodiode, and the third photodiode 41 may be a red photodiode. According to at least one example embodiment, the first through third photodiodes 21, 31, and 41 may be p-n junction diodes in which the doping regions P1 through P3 and a p-type substrate may be combined.

A floating diffusion region 23 may be formed on a side of the doping region P1 of the first photodiode 21, and a reset region 25 may be formed on a side of the floating diffusion region 23. The floating diffusion region 23 and the reset region 25 may be, for example, n+ type doping regions, and may be spaced apart from one another. A transfer gate 24 may be formed above a region between the doping region P1 and the floating diffusion region 23. The doping region P1, the floating diffusion region 23, and the transfer gate 24 may constitute a transfer transistor.

A reset gate 26 may be formed above a region between the floating diffusion region 23 and the reset region 25. The floating diffusion region 23, the reset region 25, and the reset gate 26 may constitute a reset transistor. Although not shown in FIG. 2, a drive transistor and a selection transistor may be included on a side of the doping region P1 of the first photodiode 21. The drive transistor and the selection transistor may serve as signal process control devices.

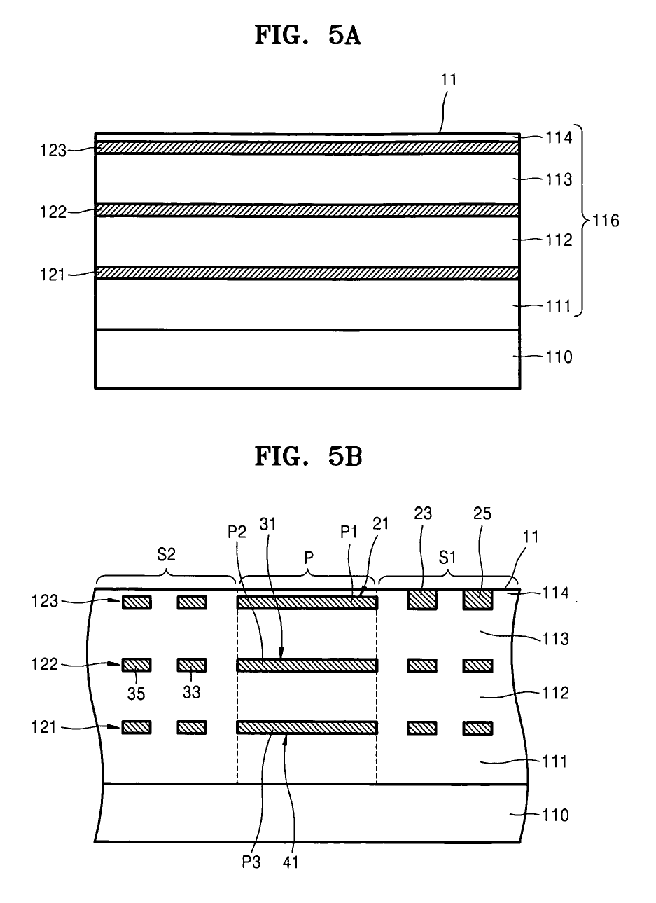

FIG. 4 is an equivalent circuit of a unit pixel according to an example embodiment. The unit pixel of FIG. 4 may be used as a blue pixel, a green pixel, and/or a red pixel of the CMOS image sensor shown in FIG. 1, for example. Referring to FIG. 4, a blue pixel of a CMOS image sensor may include a photodiode PD, a transfer transistor Tx, a reset transistor Rx, a drive transistor Dx, and/or a selection transistor Sx.

Referring to FIG. 4, the photodiode PD may receive optical energy (e.g., incident light) and generate charges in response to the received optical energy. The transfer transistor Tx may control the transport or transfer of the charges generated in the photodiode PD to a floating diffusion region FD via a transfer gate line TG. The reset transistor Rx may reset a potential energy of the floating diffusion region FD by controlling an input power V_{dd} via a reset gate line RG. The drive transistor Dx may function and/or perform as a source follower amplifier. The selection transistor Sx may be a switching device for selecting a unit pixel via a selection gate line SG. The input power V_{dd} may be output through an output line OUT via the drive transistor Dx and the selection transistor Sx.

Referring back to FIGS. 1 and 2, a floating diffusion region 33 may be formed on a side of a doping region P2 of a second photodiode 31 on a second surface 12. The second surface 12 may be formed by etching the silicon substrate 10 to a second depth d2 from the first surface 11 of the silicon substrate 10. A reset region 35 may also be formed on a side of the floating diffusion region 33 on the second surface 12. The floating diffusion region 33 and the reset region 35 may be, for example, n+type doped regions and may be formed in the same or substantially the same horizontal plane as the doping region P2. The floating diffusion region 33 and the reset region 35 may be spaced apart from one another. A transfer gate 34 may be formed above a region between the doping region P2 and the floating diffusion region 33. The doping region P2, the floating diffusion region 33, and the transfer gate 34 may constitute a transfer transistor.

A reset gate 36 may be formed above a region between the floating diffusion region 33 and the reset region 35. The floating diffusion region 33, the reset region 35, and the reset gate 36 may constitute a reset transistor. Although not shown in FIG. 2, a drive transistor and a selection transistor may be included on a side of the doping region P2 of the second photodiode 31. The drive transistor and the selection transistor may serve as signal process control devices.

As discussed above, FIG. 3 is a cross-sectional view taken along line III-III in FIG. 1.

Referring now to FIGS. 1 and 3, a doping region P3 may be formed on a third surface 13 of the silicon substrate 10. The third surface 13 may be formed by etching the silicon substrate 10 to a third depth d3. The third doping region P3 may be formed at a depth d3 deeper than the second surface 12 etched to the second depth d2. The doping region P3 and the surrounding (e.g., p-type) region around the doping region P3 may constitute a third photodiode 41. A floating diffusion region 43 may be formed on a side of the doping region P3 of the third photodiode 41. A reset region 45 may be formed on a side of the floating diffusion region 43. The floating diffusion region 43 and the reset region 45 may be doped with, for example, an n+ type impurity. The floating diffusion region 43 and the reset region 45 may be formed spaced apart from one another and/or in the same or substantially the same plane as the doping region P3.

A transfer gate 44 may be formed above a region between the third photodiode 41 and the floating diffusion region 43. The doping region P3, the floating diffusion region 43, and the transfer gate 44 may constitute a transfer transistor.

A reset gate 46 may be formed above a region between the floating diffusion region 43 and the reset region 45. The floating diffusion region 43, the reset region 45, and the reset gate 46 may constitute a reset transistor. Although not shown in FIG. 3, a drive transistor and a selection transistor may be included on a side of the doping region P3 of the third photodiode 41. The drive transistor and the selection transistor may serve as signal process control devices

The first through third photodiodes 21, 31, and 41 may be formed vertically in the same or substantially the same region of the silicon substrate 10. The signal processing devices connected to the first through third photodiodes 21, 31, and 41, respectively, may be formed on a plane corresponding to the plane in which first through third photodiodes 21, 31, and 41 are formed. The signal processing devices may be formed on respective exposed surfaces. Thus, the vertical CMOS image sensor according to example embodiments need not include a vertical wiring for external connections as in the conventional art.

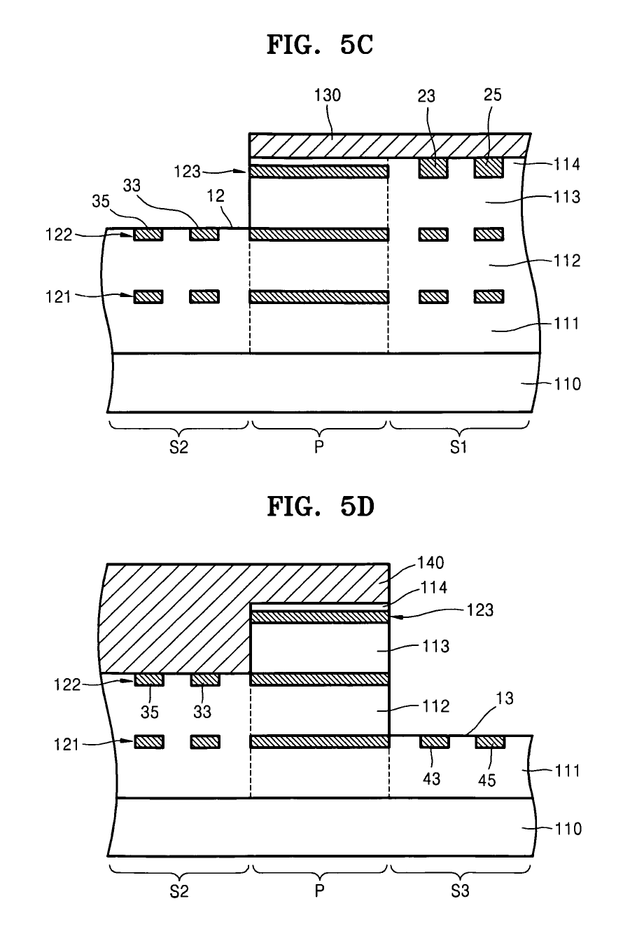

FIGS. 5A through 5D are cross-sectional views illustrating a method of fabricating a vertical CMOS image sensor according to an example embodiment. Like reference numerals are used to indicate elements substantially identical to the above-discussed example embodiment, and thus detailed descriptions will be omitted for the same of brevity.

Referring to FIG. 5A, an epitaxy layer 116 may be formed on a substrate 110. While epitaxially growing a silicon layer on the substrate 110, first and second impurities (e.g., p-type and n-type impurities) may be alternately doped during. As a result, the epitaxy layer 116 may have first through fourth doping layers of a first type (e.g., p-type) 111, 112, 113 and 1 14 and first through third doping layers of a second type (e.g., n-type) 121, 122 and 123 formed between the first through fourth doping layers 111 through 114. The first through fourth doping layers 111 through 114 may be formed to depths of about 2 μm, 0.6 μm, and 0.2 μm, respectively, from the first surface 11 of the fourth doping layer 114. The above depths may vary according to an epitaxial material and/or pixel color. The substrate 110 may be a material having a lattice constant that is the same or substantially the same as that of the epitaxy layer 116, such as a silicon substrate or the like.

The silicon doping layers may be manufactured or formed using one silicon epitaxial process by changing the impurity materials. Also, the potential profile may be controlled by controlling the concentration of impurities while epitaxially growing the doping layers. Therefore, the doping layers may be formed more precisely and/or with higher reproducibility than the doping layers formed by conventional implantation and thermal treatment.

Referring to FIG. 5B, conductive ions of a first type (e.g., p-type conductive ions) may be implanted into portions (e.g., signal processing device regions) of the epitaxial region 116 to define the photodiode region P, the floating diffusion regions 23, 33, and 43 (refer to FIG. 5D) of signal processing regions S1 through S3, and the reset regions 25, 35, and 45 (refer to FIG. 5D). In at least one example embodiment, the photodiode region P, the floating diffusion regions 23, 33, and 43 and the reset regions 25, 35, and 45 may be defined by implanting the first type conductive ions into the epitaxial layer 116, except for the photodiode region P, floating diffusion regions 23, 33, and 43, and reset regions 25, 35, and 45. In FIG. 5B, the signal processing regions S1 and S2 are shown, and the signal processing region S3 is shown in FIG. 5D.

Doping layers P1, P2, and P3 defined on the photodiode region P may be formed in the same or substantially the same region of the epitaxy layer 116.

Ions of a second type (e.g., n+ ions) may be implanted in the floating diffusion region 23 and the reset region 25 of the signal processing region S1 through the first surface 11. Although not shown in FIG. 5B, the first and second ion implantations may be performed in electrode regions of a drive transistor and a selection transistor in the same or substantially the same manner. The second doping (e.g., the n+ doping) may increase the concentration of doping ions (e.g., n doping ions) in the floating diffusion region 23 and the reset region 25 so that charges gathered in the first photodiode 21 may move to the floating diffusion region 23 and the reset region 25 due to the potential difference.

In the photodiode region P, the third doping region (e.g., n-type) P1 and the perimeter of the first-type (e.g., p type) region form the first photodiode 21, the second (e.g., n-type) doping region P2 and the perimeter of the first-type (e.g., p type) region form the second photodiode 31, and the first (e.g., n-type) doping region P3 and the perimeter of the first-type (e.g., p type) region form the third photodiode 41. The first through third photodiodes 21, 31, and 41 may be p-n junction diodes.

Referring to FIG. 5C, a photoresist 130 may be formed on the photodiode region P, the first and third signal processing regions S1 and S3. The second signal processing region S2 not covered by the photoresist 130 may be etched until a second surface 12 is exposed. As shown in FIG. 5C, the second surface 12 may be a portion of a second (e.g., n-type) doping layer 122. The floating diffusion region 33 and the reset region 35 in the second signal processing region S2 may be doped with a second (e.g., n+ type) impurity. Although not shown in FIG. 5C, electrode regions of a drive transistor and a selection transistor of the second signal processing region S2 may be doped with a second (e.g., n+ type) impurity in the same or substantially the same manner.

Referring to FIG. 5D, a photoresist 140 may be formed on the photodiode region P and the first and second signal processing regions S1 and S2. The third signal processing region S3 not covered by the photoresist 140 may be etched until a third surface 13 is exposed. As shown in FIG. 5D, the third surface 13 may be a portion of a first (e.g., n-type) doping layer. The floating diffusion region 43 and the reset region 45 in the third signal processing region S3 may be doped with the second (e.g., n+ type) impurity. Although not shown in FIG. 5D, electrode regions of a drive transistor and a selection transistor of the third signal processing region S3 may be doped with the second (e.g., n+type) impurity in the same or substantially the same manner.

A dielectric layer and wirings may be formed on the epitaxy layer 116 using a CMOS process well known in the art, and thus, the detailed description thereof will be omitted.

In methods of fabricating vertical CMOS image sensors according to example embodiments, doping processes (e.g., n+ doping processes) and etching processes may be sequentially performed from the first surface, however, example embodiments are not limited thereto. For example, the etching for forming the third signal processing region S3 may be performed prior to etching for forming the second signal processing region S2. Also, the doping process (e.g., the n+ doping process) may be performed after completing all or substantially all of the etching processes.

As described above, vertical CMOS image sensors according to example embodiments may detect three pixels of light in one photodiode region, thereby having increased light detection efficiency per unit area. Also, because a color filter may be omitted, optical sensitivity may be increased and the vertical CMOS image sensor may have a wider dynamic range. Because a signal processing device region and a corresponding photodiode region may be formed on the same or substantially the same plane, wirings for connecting the signal processing device regions and the photodiode region may be omitted, and a more compact vertical CMOS image sensor may be fabricated.

Vertical CMOS image sensors-according to example embodiments may be manufactured using a simplified process because device regions may be formed using one epitaxial process and one p-type implantation.

While the present invention has been particularly shown and described with reference to example embodiments thereof, it will be understood by those of ordinary skill in the art that various changes in form and details may be made therein without departing from the spirit and scope of the present invention as defined by the following claims.

What is claimed is:

1. A vertical image sensor comprising:
a plurality of photodiodes vertically formed in a substrate; and
a plurality of signal processing devices corresponding to the plurality of photodiodes, the plurality of signal processing devices being configured to transmit signals generated from the plurality of photodiodes; wherein
each signal processing device is formed on a same plane with a corresponding one of the plurality of photodiodes.

2. The vertical image sensor of claim 1, wherein the plurality of photodiodes are aligned vertically with one another such that light incident on the vertical CMOS image sensor impinges an uppermost one of the plurality of photo diodes prior to impinging a lower of the plurality of photodiodes.

3. The vertical image sensor of claim 1, wherein at least a portion of the signal processing devices include,
a floating diffusion region for receiving charges from the corresponding photodiode, wherein
a first doping region of the photodiode and the floating diffusion region form a transfer transistor having a transfer gate disposed above a region between the first doping region and the floating diffusion region.

4. The vertical image sensor of claim 3, wherein each of the plurality of photodiodes includes,
an n-type doping region and a p-type region formed around the n-type doping region, wherein
the floating diffusion region is an n+type doping region.

5. The vertical image sensor of claim 3, wherein the n-type doping regions of the plurality of photodiodes are formed vertically in the same region of the substrate.

6. The vertical image sensor of claim 1, wherein the plurality of photodiodes includes three photodiodes.

7. The vertical image sensor of claim 6, wherein the three photodiodes are regions that detect blue, green, and red light, respectively.

8. The vertical image sensor of claim 1, wherein the plurality of photodiodes includes,
a first photodiode formed at a first depth from a surface of the substrate,
a second photodiode formed at a second depth from the surface of the substrate, and
a third photodiode formed at a third depth from the surface of the substrate, wherein
the first depth is less than the second depth, and
the second depth is less than the third depth.

9. The vertical image sensor of claim 8, wherein the first, second and third photodiodes are vertically aligned with one another.

10. The vertical image sensor of claim 8, wherein the plurality of signal processing devices further include,
a first signal processing device formed at a surface of the substrate,
a second signal processing device formed at the second depth from the surface of the substrate, and
a third signal processing device formed at the third depth from the surface of the substrate.

11. A method of fabricating a vertical image sensor, the method comprising:
forming a plurality of vertically aligned photodiodes in a substrate; and
forming a plurality of signal processing devices corresponding to the plurality of photodiodes, the plurality of signal processing devices being formed so as to transmit signals generated from the plurality of photodiodes; wherein
each signal processing device is formed on a same plane with a corresponding one of the plurality of photodiodes.

12. The method of claim 11, wherein the forming of the plurality of vertically aligned photodiodes in a substrate, and the forming of the plurality of signal processing devices further includes,
forming an epitaxy layer on the substrate, the epitaxy layer including a plurality of first doping layers and a plurality of second doping layers formed alternately, the first doping layers and the second doping layers being doped with different impurities;
defining a plurality of vertically aligned photodiode regions and a plurality of signal processing device regions connected to respective photodiode regions by implanting a first impurity into the epitaxy layer;
doping a signal processing device region connected to a first photodiode through a first surface of the epitaxy layer;
forming a second surface exposing a portion of a second of the plurality of second doping layers by etching a signal processing region connected to a second photodiode from the first surface of the epitaxy layer; and
doping a signal processing device region in the second surface.

13. The method of claim 12, wherein the plurality of first doping layers are p-type doping layers, and the plurality of second doping layers are n-type doping layers.

14. The method of claim 12, wherein the epitaxy layer is a silicon layer.

15. The method of claim 12, further including,
forming a third surface exposing a portion of a third of the plurality of second doping layers by etching a signal processing region connected to a third photodiode from the first surface of the epitaxy layer, and
doping on the signal processing device region in the third surface.

16. The method of claim 15, wherein the defining of the plurality of signal processing device regions includes,
defining a first signal processing device region on the first surface,
defining a second signal processing device region on the second surface, and
defining a third signal processing device region on the third surface, the second surface being a first depth below the first surface, and the third surface being a second depth below the first surface, the second depth being greater than the first depth.

17. The method of claim 11, wherein the forming of the plurality of vertically aligned photodiodes includes,
forming a first photodiode at a first depth from a surface of the substrate,
forming a second photodiode at a second depth from the surface of the substrate, and
forming a third photodiode at a third depth from the surface of the substrate, wherein
the first depth is less than the second depth, and
the second depth is less than the third depth.

18. The method of claim 17, wherein the forming of the plurality of signal processing devices further includes,
forming a first signal processing device at a surface of the substrate,
forming a second signal processing device at a second depth from the surface of the substrate, and
forming a third signal processing device at the third depth from the surface of the substrate.
